(19) United States
(12) Patent Application Publication
(10) Pub. No.: US 2026/0177432 A1
(43) Pub. Date: Jun. 25, 2026

(54) TEMPERATURE DETECTING ELEMENT, SEMICONDUCTOR MODULE, AND MANUFACTURING METHOD OF TEMPERATURE DETECTING ELEMENT

(71) Applicant: FUJI ELECTRIC CO., LTD., Kanagawa (JP)

(72) Inventors: Jyunnosuke SANO, Matsumoto-city (JP); Soichi YOSHIDA, Matsumoto-city (JP)

(21) Appl. No.: 19/369,294

(22) Filed: Oct. 26, 2025

(30) Foreign Application Priority Data
Dec. 23, 2024 (JP) 2024-226688

(51) Int. Cl. G01K 7/01; H01L 21/02; H01L 23/34; H01L 25/065

(52) U.S. Cl. CPC G01K 7/01; H10W 40/00; H10W 90/00; H10P 14/3456; H10P 14/6306

(57) ABSTRACT

Provided is a temperature detecting element, including: an anode electrode and a cathode electrode provided above the upper surface of the semiconductor substrate; a main cathode region of a first conductivity type connected to the cathode electrode; a main anode region of a second conductivity type, which is provided in contact with the main cathode region and connected to the anode electrode; and a conductive portion that connects one of the anode electrode and the cathode electrode to the lower surface of the semiconductor substrate at an identical potential.

The contents of the following patent application (s) are incorporated herein by reference:
NO. 2024-226688 filed in JP on Dec. 23, 2024.

### BACKGROUND

### 1. Technical Field

The present invention relates to a temperature detecting element, a semiconductor module, and a manufacturing method of the temperature detecting element.

### 2. Related Art

In Patent document 1, a power module is disclosed to include “a temperature sensor for detecting the temperature of a power semiconductor device (claim 1)”. In Patent document 2, a semiconductor device is disclosed to include “a semiconductor base wafer having at least one p-n junction portion (claim 1)”.
Patent Document 1: Japanese Patent Application Publication No. 2019-149439
Patent Document 2: Japanese Patent Application Publication No. 2005-045120

The summary clause does not necessarily describe all necessary features of the embodiments of the present invention. The present invention may also be a sub-combination of the features described above.

### BRIEF DESCRIPTION OF THE DRAWINGS

FIG. 1 illustrates a cross-sectional view showing an example of a semiconductor module 200 according to one embodiment of the present invention.

FIG. 2 illustrates a cross-sectional view showing a configuration example of a temperature detecting element 100.

FIG. 3 illustrates a cross-sectional view showing another example of the temperature detecting element 100.

FIG. 4 illustrates an exemplary structure of the temperature detecting element 100 in a top view.

FIG. 5 illustrates an exemplary arrangement of a through-wire line 14.

FIG. 6 illustrates another exemplary arrangement of the through-wire line 14.

FIG. 7 illustrates another exemplary arrangement of the through-wire line 14.

FIG. 8 illustrates another exemplary arrangement of the through-wire line 14.

FIG. 9 illustrates another exemplary arrangement of the through-wire line 14.

FIG. 10 illustrates another exemplary arrangement of the through-wire line 14.

FIG. 11 illustrates an example of an A-A cross-section in FIG. 5.

FIG. 12A illustrates another exemplary structure of the semiconductor module 200.

FIG. 12B illustrates another exemplary structure of the semiconductor module 200.

FIG. 12C illustrates another exemplary structure of the semiconductor module 200.

FIG. 13 illustrates a perspective view showing an example of the appearance of the semiconductor module 200.

FIG. 14 illustrates a perspective view showing an example of a circuit housed in an enclosure 220.

FIG. 15 illustrates a flow showing an example of a manufacturing method of the temperature detecting element 100.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicate a height direction with respect to the ground. It is to be noted that a +Z axis direction and a −Z axis direction are directions opposite to each other. When the Z axis direction is described without describing a sign, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, when described as p type or n type in lowercase letters, only the conductivity type is indicated, and the magnitude of the doping concentration is not indicated. In the present specification, a unit system is an SI unit system unless otherwise noted. Although a unit of a length may be expressed in cm, various calculations may be performed after conversion to meters (m).

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. Further, in a region of the n type, the donor concentration is sufficiently higher than the acceptor concentration, and thus the carrier concentration of the region may be set as the donor concentration. Similarly, in a region of the p type, the carrier concentration of the region may be set as the acceptor concentration. In the present specification, the doping concentration of the n type region may be referred to as the donor concentration, and the doping concentration of the p type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or/cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of the chemical concentrations of these. On the other hand, in the silicon semiconductor, a donor concentration of hydrogen serving as a donor is approximately 0.1% to 10% of the chemical concentration of hydrogen.

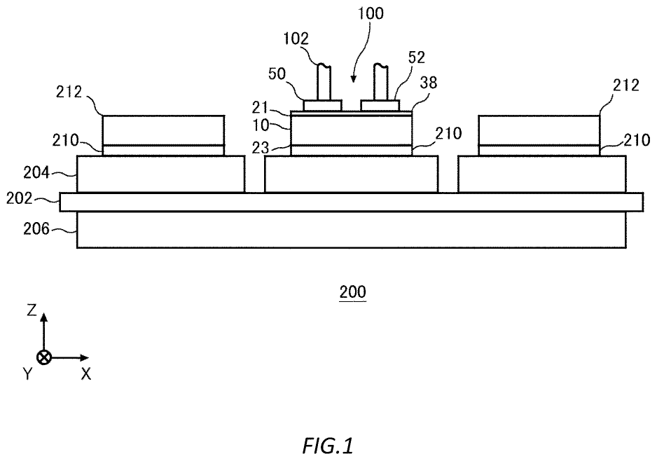

FIG. 1 illustrates a cross-sectional view showing an example of a semiconductor module 200 according to one embodiment of the present invention. The semiconductor module 200 includes one or more semiconductor chips 212 and a temperature detecting element 100. The semiconductor chip 212 may include a power semiconductor device such as an IGBT (Insulated Gate Bipolar Transistor). The temperature detecting element 100 includes a p-n junction diode. By measuring characteristics such as a voltage or current of the p-n junction diode, calculate the ambient temperature of the temperature detecting element 100. The semiconductor module 200 may control the semiconductor chip 212 based on the sensed temperature of the temperature detecting element 100. For example, when the sensed temperature is equal to or higher than a standard temperature, the semiconductor module 200 may control the semiconductor chip 212 to be in an off state to shut down the current flowing to the semiconductor chip 212.

In the present example, the semiconductor module 200 further includes an insulating substrate 202, a metal layer 206 and a wiring layer 204. The insulating substrate 202, the metal layer 206 and the wiring layer 204 function as a circuit board for mounting the temperature detecting element 100. The insulating substrate 202 is a wafer formed of an insulating material such as plastic or ceramic. The metal layer 206 is provided on a lower surface of the insulating substrate 202. The metal layer 206 is formed of a metal such as copper as an example. The metal layer 206 may be connected to a heat radiator such as a heat radiation fin. The wiring layer 204 is provided on the upper surface of the insulating substrate 202. The wiring layer 204 is formed of a metal such as copper as an example. The insulating substrate 202, the metal layer 206 and the wiring layer 204 may be a so-called DCB (Direct Copper Bonding) wafer.

Each semiconductor chip 212 may be connected to the wiring layer 204 in a conductive junction portion 210 such as a solder. Although the semiconductor chip 212 has one or more electrodes, the electrodes are omitted in FIG. 1.

The temperature detecting element 100 is formed on the semiconductor substrate 10 with an upper surface 21 and a lower surface 23. For example, the semiconductor substrate 10 may be formed of silicon, or formed of a compound semiconductor such as SiC or GaN. The lower surface 23 of the semiconductor substrate 10 is connected to the wiring layer 204 via the junction portion 210. Although the temperature detecting element 100 has a p-n junction diode above the upper surface 21 of the semiconductor substrate 10 or inside the semiconductor substrate 10, it is omitted in FIG. 1. The upper surface 21 of the semiconductor substrate 10 is covered by the interlayer dielectric film 38. The interlayer dielectric film 38 may be an oxide film such as BPSG, BSG or HTO, or a nitride film, or a film composed of two or more of these films stacked together.

The anode electrode 50 and the cathode electrode 52 are provided above the upper surface 21 of the semiconductor substrate 10. The interlayer dielectric film 38 is provided between the upper surface 21 of the semiconductor substrate 10 and a set of the anode electrode 50 and the cathode electrode 52. The anode electrode 50 and the cathode electrode 52 are connected to another circuit such as a measurement circuit by each metal connection wiring line 102. The connection wiring line 102 is a rod-shaped pin, a board-shaped lead frame, or a linear wire or the like.

When there occurs a large potential difference occurs between the wiring layer 204 for mounting the temperature detecting element 100 and the anode electrode 50 or cathode electrode 52 of the temperature detecting element 100, discharge may occur between the wiring layer 204 and the temperature detecting element 100. For example, when the potential of the wiring layer 204 is floating, the potential difference may increase. In the present example, the temperature detecting element 100 and the semiconductor module 200 suppress the discharge described above by electrically connecting the wiring layer 204 to the anode electrode 50 or the cathode electrode 52.

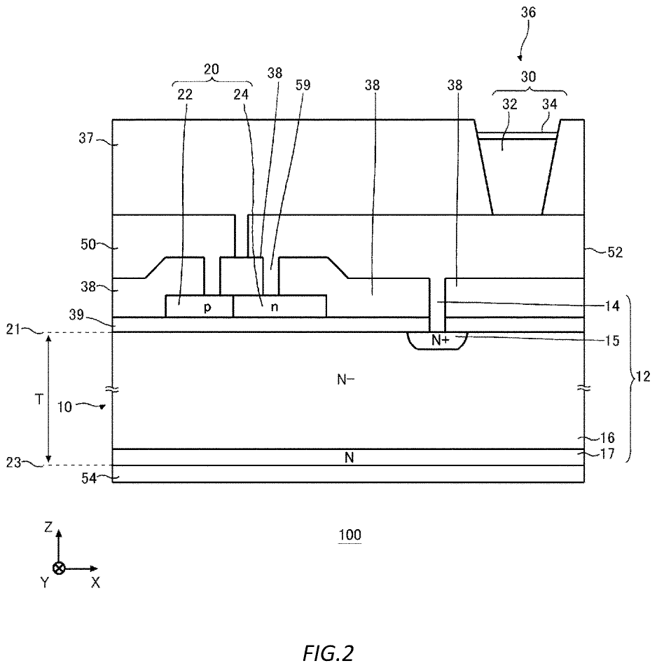

FIG. 2 illustrates a cross-sectional view showing a configuration example of the temperature detecting element 100. In the present example, the semiconductor substrate 10 has a bulk that is an N− type wafer. In addition to the configuration shown in FIG. 1, the temperature detecting element 100 includes a p-n junction diode 20 and a conductive portion 12. As shown in FIG. 2, the temperature detecting element 100 may further include at least one of the initial oxide film 39 or the lower-surface electrode 54. The initial oxide film 39 may be a film formed by oxidizing the semiconductor substrate 10. In addition, the temperature detecting element 100 may further include a protective film 37 and a pad portion 36.

The p-n junction diode 20 has a p type main anode region 22 and an n type main cathode region 24. The main anode region 22 and the main cathode region 24 are provided to contact each other. The main anode region 22 and the main cathode region 24 may be formed on a polycrystalline semiconductor film (for example, polysilicon) doped with impurities. The main anode region 22 and the main cathode region 24 may be provided above the upper surface 21 of the semiconductor substrate 10. In the present example, an initial oxide film 39 is provided between a set of the main anode region 22 and the main cathode region 24 and the upper surface 21 of the semiconductor substrate 10. The main anode region 22 and the main cathode region 24 may be provided on the upper surface of the initial oxide film 39. The initial oxide film 39 is provided between the interlayer dielectric film 38 and the upper surface 21 of the semiconductor substrate 10. The interlayer dielectric film 38 may be provided between a set of the main anode region 22 and the main cathode region 24 and the upper surface 21 of the semiconductor substrate 10.

The main anode region 22 is connected to the anode electrode 50. The main cathode region 24 is connected to the cathode electrode 52. In FIG. 2, the connection wiring line 102 connected to each electrode is omitted. The interlayer dielectric film 38 may be provided between the anode electrode 50 and the cathode electrode 52.

The conductive portion 12 connects either the anode electrode 50 or the cathode electrode 52 to the lower surface 23 of the semiconductor substrate 10 at the same potential. The conductive portion 12 in each example of the present specification electrically connects the cathode electrode 52 and the lower surface 23 of the semiconductor substrate 10. Also, when the conductive portion 12 connects the anode electrode 50 and the lower surface 23, the conductive portion 12 may have a structure and an arrangement similar to each example of the present specification with respect to the anode electrode 50.

In the present example, the conductive portion 12 is provided to penetrate the interlayer dielectric film 38, and has a through-wire 14 that connects the cathode electrode 52 and the semiconductor substrate 10. In the present example, the through-wire 14 is provided to penetrate the initial oxide film 39 as well. The through-wire 14 may be formed of a metal material. The through-wire 14 may be formed of the same material as the cathode electrode 52, or may be formed of a different material. The cathode electrode 52 may include aluminum, for example. The through-wire 14 may include aluminum. The through-wire 14 may be a plug formed of tungsten or the like.

At least a portion of the conductive portion 12 may be provided inside the semiconductor substrate 10. In the present example, the conductive portion 12 has a conductive region of an n type provided inside the semiconductor substrate 10. The conductive region has a high concentration region 15 and a low concentration region 16. The conductive region may further have a lower surface region 17. In the present example, the through-wire 14 connects the cathode electrode 52 to the conductive region by being connected to the high concentration region 15.

The high concentration region 15 is an N type region exposed on the upper surface 21 of the semiconductor substrate 10. The high concentration region 15 may be selectively provided on a portion of the upper surface 21 of the semiconductor substrate 10. The high concentration region 15 may be provided at a position not overlapping the p-n junction diode 20 in a top view. A top view refers to observing each component by projecting it onto a plane parallel to the upper surface 21 of the semiconductor substrate 10. The high concentration region 15 may be formed by implanting dopant ions such as phosphorus or arsenic via a through hole formed in the interlayer dielectric film 38.

The low concentration region 16 is an N− type region, provided between the high concentration region 15 and the lower surface 23 of the semiconductor substrate 10, with a concentration lower than the high concentration region 15. The low concentration region 16 may be provided in a range wider than the high concentration region 15 in the top view. The low concentration region 16 may be provided below the main anode region 22 and the main cathode region 24. The low concentration region 16 may be exposed on the upper surface 21 of the semiconductor substrate 10. The low concentration region 16 may be provided in a region where no high concentration region 15 is provided on the upper surface 21 of the semiconductor substrate 10. The low concentration region 16 may be provided throughout the semiconductor substrate 10 in the top view.

The lower surface region 17 is an N type region provided between the low concentration region 16 and the lower surface 23 of the semiconductor substrate 10, with a concentration higher than the low concentration region 16. The lower surface region 17 may have the same concentration as the high concentration region 15, or may have a concentration higher or lower than the high concentration region 15. The lower surface region 17 may be provided in a range wider than the high concentration region 15 in the top view. In the present example, the lower surface region 17 is provided throughout the lower surface 23 of the semiconductor substrate 10.

With such a configuration, the lower surface 23 of the semiconductor substrate 10 and the cathode electrode 52 are connected electrically by the conductive portion 12. The lower surface 23 of the semiconductor substrate 10 is electrically connected to the wiring layer 204 by the junction portion 210 shown in FIG. 1. The lower-surface electrode 54 may be provided on the lower surface 23 of the semiconductor substrate 10. The lower-surface electrode 54 may cover the entire lower surface 23. The lower-surface electrode 54 includes a metal such as aluminum, for example. The lower-surface electrode 54 is connected to the junction portion 210. The strength of the connection with the junction portion 210 can be improved by providing the lower-surface electrode 54. According to the present example, the wiring layer 204 for mounting the temperature detecting element 100 becomes at the same potential as the cathode electrode 52. Therefore, the discharge between the temperature detecting element 100 and the wiring layer 204 can be suppressed. For example, in an isolation test of the semiconductor module 200, even if a high voltage is applied to the temperature detecting element 100, the discharge between the temperature detecting element 100 and the wiring layer 204 can be suppressed.

A thickness between the upper surface 21 and the lower surface 23 of the semiconductor substrate 10 is referred to as T. When at least one of the upper surface 21 or the lower surface 23 is not flat, the thickness T may use a minimum value of the distance between the upper surface 21 and the lower surface 23. The thickness T may be 10 μm or more and 300 μm or less. The thickness T may be 20 μm or more, or 50 μm or more, or 100 μm or more. The thickness T may be 200 μm or less, or 100 μm or less.

The resistivity of the low concentration region 16 may be 100 Ωcm or less. By reducing the resistivity of the low concentration region 16, the potential difference between the cathode electrode 52 and the lower surface 23 can be reduced. The resistivity of the low concentration region 16 may be 80 Ωcm or less, or 60 Ωcm or less, or 30 Ωcm or less, or 10 Ωcm or less, or 1 Ωcm or less, or 0.1 Ωcm or less, or 0.01 Ωcm or less. The resistivity of the low concentration region 16 may be 0.001 Ωcm or more.

The doping concentration of the low concentration region 16 may be 1×10¹³/cm³ or more. By increasing the doping concentration of the low concentration region 16, the resistivity can be reduced. The doping concentration of the low concentration region 16 may be or more, or 1×10¹⁴/cm³ or more, or 1×10¹⁵/cm³ or more, or 1×10¹⁶/cm³ or more, or 1×10¹⁷/cm³ or 1×10¹⁸/cm³ or more, or 1×10¹⁹/cm³ or more. The doping concentration of the low concentration region 16 may be 1×10²⁰/cm³ or less. When the doping concentration of the low concentration region 16 is 1×10¹⁴/cm³, the resistivity of the low concentration region 16 is approximately 46 Ωcm, and when the doping concentration is 1×10¹⁹/cm³, the resistivity is approximately 0.0054 Ωcm.

A protective film 37 formed of polyimide or the like may be provided on the anode electrode 50 and the cathode electrode 52. A pad portion 36 for electrically connecting to the anode electrode 50 and the cathode electrode 52 may be provided on the protective film 37. The pad portion 36 may be connected to the connection wiring line 102. The pad portion 36 has an aperture provided on the protective film 37. The anode electrode 50 or the cathode electrode 52 may be exposed at the bottom of the aperture to function as the pad portion 36. A plating portion 30 covering the anode electrode 50 or the upper surface of the cathode electrode 52 may be provided in the aperture. The plating portion 30 may have an electroless nickel plating layer 32 provided on the upper surface of the anode electrode 50 or the cathode electrode 52. The plating portion 30 may further have a gold plating layer 34 provided on the upper surface of the electroless nickel plating layer 32.

One or more contact holes 59 may be provided on the interlayer dielectric film 38. The contact hole 59 connects the anode electrode 50 or the cathode electrode 52 to the p-n junction diode 20. The contact hole 59 may be provided in another position in the interlayer dielectric film 38. At least a portion of the through-wire 14 may be provided in the contact hole 59.

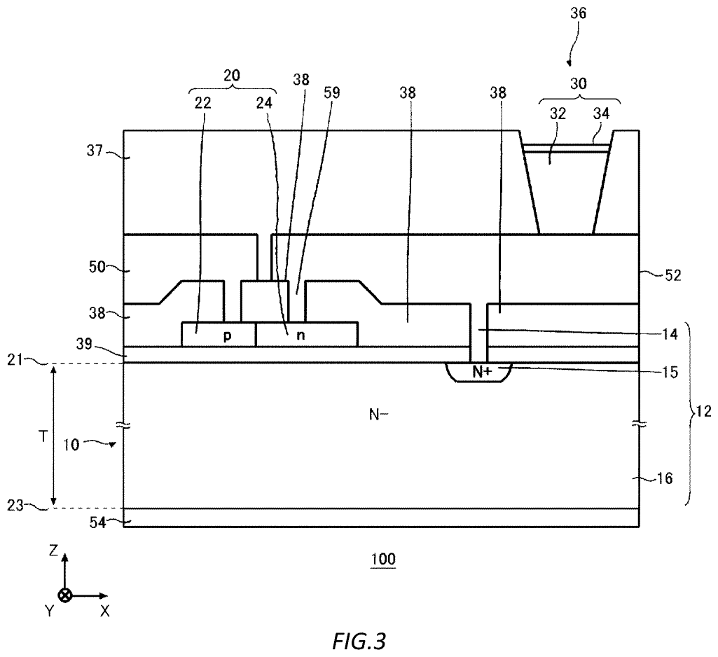

FIG. 3 illustrates a cross-sectional view showing another example of the temperature detecting element 100. In the present example, the temperature detecting element 100 is different from the example shown in FIG. 2 in that it does not include the lower surface region 17. Other structures are similar to the example of FIG. 2.

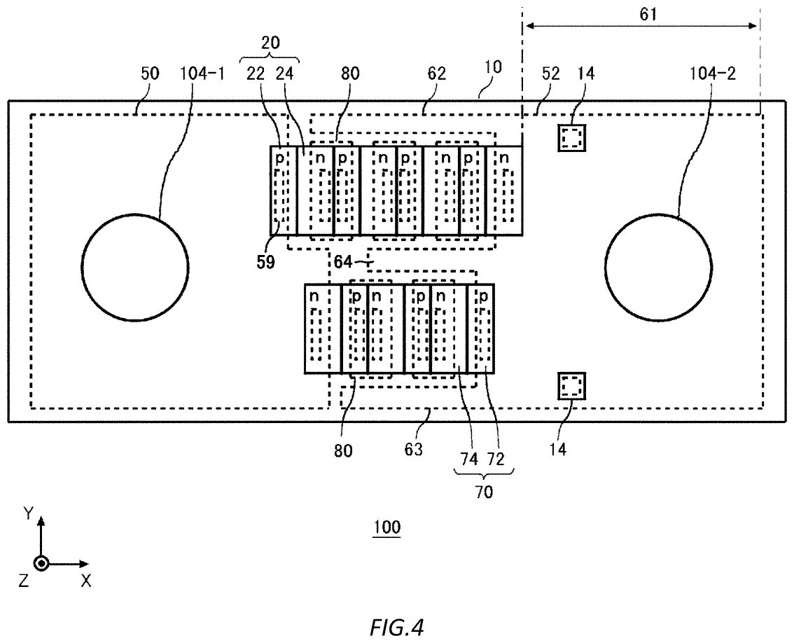

FIG. 4 illustrates an exemplary structure of the temperature detecting element 100 in the top view. In the present example, the temperature detecting element 100 has a semiconductor substrate 10, a p-n junction diode 20, a p-n junction diode 70, an anode electrode 50, a cathode electrode 52, a connection electrode 80, a through-wire 14 and a contact portion 104 in the top view, and in FIG. 4, the anode electrode 50, the cathode electrode 52, the connection electrode 80 and the contact hole 59 are shown by dashed lines, and the other structures are shown by solid lines.

The p-n junction diode 20 has a main anode region 22 and a main cathode region 24 arranged side by side in a first direction. In the present example, the first direction is an X axis direction. The main anode region 22 and the main cathode region 24 are each repeatedly arranged alternately one or more times. In the present example, the main anode regions 22 and the main cathode regions 24 are repeatedly arranged alternately for a plurality of times. The main anode regions 22 are arranged in one end portion in the X axis direction of the p-n junction diode 20, and are connected to the anode electrode 50. The main cathode regions 24 are arranged in the other end portion in the X axis direction of the p-n junction diode 20, and are connected to the cathode electrode 52.

In the present example, the p-n junction diode 20 includes a plurality of diode portions. Each main anode region 22, and the main cathode region 24, which are arranged to contact the cathode electrode 52 side with respect to the main anode region 22, constitute one diode portion. The connection electrode 80 is connected to the main cathode region 24 of the one diode portion and the main anode region 22 of another adjacent diode portion on the cathode electrode 52 side. In this manner, the p-n junction diode 20 includes a plurality of diode portions connected in series between the anode electrode 50 and the cathode electrode 52 in a forward direction.

The p-n junction diode 70 has a sub anode region 72 and a sub cathode region 74 arranged side by side in the X axis direction. Each sub anode region 72 and each sub cathode region 74 are repeatedly arranged alternately one or more times. In the present example, the sub anode regions 72 and the sub cathode regions 74 are repeatedly arranged alternately for a plurality of times. The sub cathode regions 74 are arranged in one end portion in the X axis direction of the p-n junction diode 70, and are connected to the anode electrode 50. The sub anode regions 72 are arranged in the other end portion in the X axis direction of the p-n junction diode 70, and are connected to the cathode electrode 52.

In the present example, the p-n junction diode 70 includes a plurality of diode portions. Each sub anode region 72, and the sub cathode region 74, which is arranged to contact the anode electrode 50 side with respect to the sub anode region 72, constitutes one diode portion. The connection electrode 80 is connected to the sub cathode region 74 of the one diode portion and the sub anode region 72 of another adjacent diode portion on the anode electrode 50 side. In this manner, the p-n junction diode 70 includes a plurality of diode portions connected in series between the anode electrode 50 and the cathode electrode 52 in a reverse direction. That is, the sub cathode regions 74 and the sub anode regions 72 are provided in reverse parallel to the main anode regions 22 and the main cathode regions 24 between the anode electrode 50 and the cathode electrode 52.

The p-n junction diode 70 functions as a protective element for preventing overvoltage from being applied to the p-n junction diode 20. The number of times for which the sub anode regions 72 and the sub cathode regions 74 are repeatedly arranged may be less than the number of times for which the main anode regions 22 and the main cathode regions 24 are repeatedly arranged. That is, the number of series connections of diode portions included in the p-n junction diode 70 may be less than the number of series connections of diode portions included in the p-n junction diode 20. In another example, the p-n junction diode 70 may be used as a temperature detecting element by detecting characteristics of the p-n junction diode 70. For example, it is possible to apply a high voltage on the cathode electrode 52 and apply a low voltage on the anode electrode 50 to sense voltage-current characteristics of the p-n junction diode 70.

The contact portion 104 described above is a portion where a set of the anode electrode 50 and the cathode electrode 52 is brought into contact with each connection wiring line 102. In the example shown in FIG. 4, the contact portion 104-1 corresponds to the anode electrode 50, and the contact portion 104-2 corresponds to the cathode electrode 52. When the connection wiring line 102 is connected to each electrode by a joining material such as solder, the contact portion 104 may be a portion where each electrode is brought into contact with the joining material.

In the present example, the cathode electrode 52 has a first portion 61, a second portion 62, a third portion 63 and a fourth portion 64. The first portion 61 is arranged side by side with the main anode region 22 and the main cathode region 24 in the X axis direction. The first portion 61 may be arranged side by side with the sub anode region 72 and the sub cathode region 74 in the X axis direction. As shown in FIG. 4, in the cathode electrode 52, the portion arranged outside the p-n junction diode 20 in the X axis direction may be referred to as the first portion 61.

The second portion 62 is provided to extend from the first portion 61 to a position arranged side by side with the p-n junction diode 20 in the Y axis direction. In the present example, the second portion 62 extends to a region outside the p-n junction diode 20 in the Y axis direction. A region outside the p-n junction diode 20 is a region sandwiched between the p-n junction diode 20 and the end side of the semiconductor substrate 10 in the Y axis direction. In the cathode electrode 52, the portion sandwiched between the p-n junction diode 20 and the end side of the semiconductor substrate 10 in the Y axis direction may be referred to as the second portion 62.

The third portion 63 is provided to extend from the first portion 61 to a position arranged side by side with the p-n junction diode 70 in the Y axis direction. In the present example, the third portion 63 extends to a region outside the p-n junction diode 70 in the Y axis direction. The region outside the p-n junction diode 70 is a region sandwiched between the p-n junction diode 70 and the end side of the semiconductor substrate 10 in the Y axis direction. In the cathode electrode 52, the portion sandwiched between the p-n junction diode 70 and the end side of the semiconductor substrate 10 in the Y axis direction may be referred to as the third portion 63.

The fourth portion 64 is provided to extend from the first portion 61 to a position sandwiched between the p-n junction diode 20 and the p-n junction diode 70 in the Y axis direction. In the cathode electrode 52, the portion sandwiched between the p-n junction diode 20 and the p-n junction diode 70 in the Y axis direction may be referred to as the fourth portion 64.

In the present example, the through-wire 14 is provided at a position overlapping the cathode electrode 52. An area S2 of the through-wire 14 may be smaller than an area S1 of the contact portion 104-2. A plurality of through-wires 14 may be provided for the cathode electrode 52. In this case, the total area of the plurality of through-wires 14 is referred to as the area S2. The area S2 may be half or less, or 10% or less of the area S1. The current flowing through the lower surface 23 via the through-wire 14 can be suppressed by reducing the area S2. The area of the through-wire 14 may be the area of the portion contacting the semiconductor substrate 10.

Each through-wire 14 may be provided in a region not overlapping the contact portion 104-2. In this manner, the formation of a step on the surface of the cathode electrode 52 in the contact portion 104-2 can be suppressed. Therefore, the reliability of the connection between the connection wiring line 102 and the cathode electrode 52 can be improved.

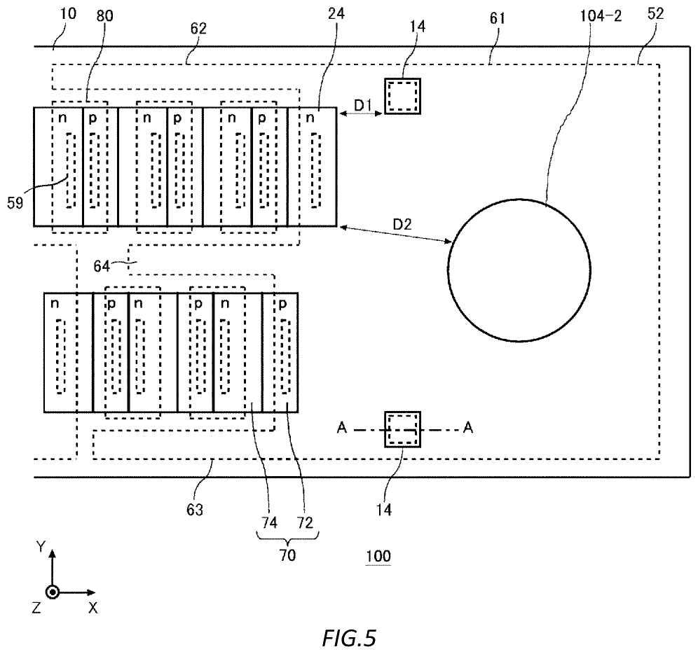

FIG. 5 illustrates an exemplary arrangement of the through-wire 14. In the present example, the through-wire 14 is closer to the p-n junction diode 70 than the contact portion 104-2. In the present example, a distance between the p-n junction diode 70 and the through-wire 14 in the top view is referred to as D1, and a distance between the p-n junction diode 70 and the contact portion 104-2 in the top view is referred to as D2. The distance D1 is smaller than the distance D2. The distance D1 may be half or less of the distance D2. In order to provide the through-wire 14, the semiconductor substrate 10 may not be expanded outside the contact portion 104-2 by arranging the through-wire 14 near the p-n junction diode 70. Therefore, the temperature detecting element 100 can be easily miniaturized.

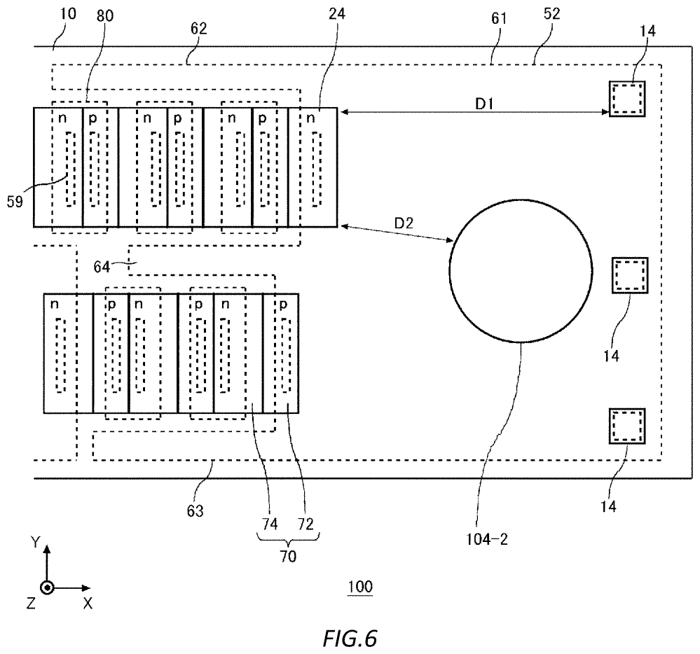

FIG. 6 illustrates another exemplary arrangement of the through-wire 14. In the present example, the through-wire 14 is further away from the p-n junction diode 70 than the contact portion 104-2. That is, in the present example, the distance D1 is larger than the distance D2. The distance D1 may be twice or more than the distance D2. The through-wire 14 may be arranged outside the contact portion 104-2 in the X axis direction. The current flowing from the p-n junction diode 70 to the through-wire 14 can be suppressed by arranging the through-wire 14 far from the p-n junction diode 70. Therefore, the impact on temperature detection due to the provision of the through-wire 14 can be reduced. At least one through-wire 14 may be arranged on the extension of the straight line connecting the p-n junction diode 70 and the contact portion 104-2.

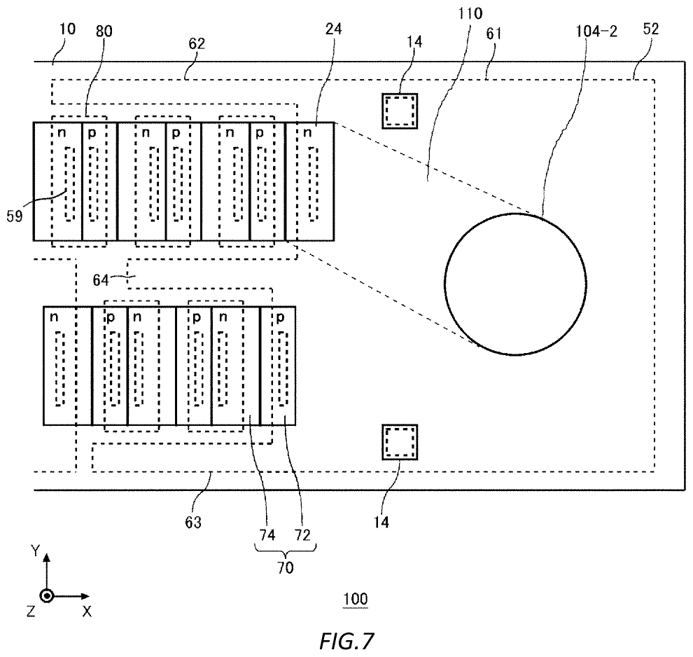

FIG. 7 illustrates another exemplary arrangement of the through-wire 14. In the present example, a region between the contact portion 104-2 and the p-n junction diode 20 is referred to as a middle region 110. The middle region 110 may be a region between the main cathode region 24 connected to the cathode electrode 52 and the contact portion 104-2. The middle region 110 is a main path through which the current flows from the p-n junction diode 20 to the contact portion 104-2.

At least one through-wire 14 may be provided outside the middle region 110. In this manner, the current flowing from the p-n junction diode 20 to the through-wire 14 can be suppressed. Half or more of the through-wire 14 may be arranged outside the middle region 110, and the entire through-wire 14 may be arranged outside the middle region 110.

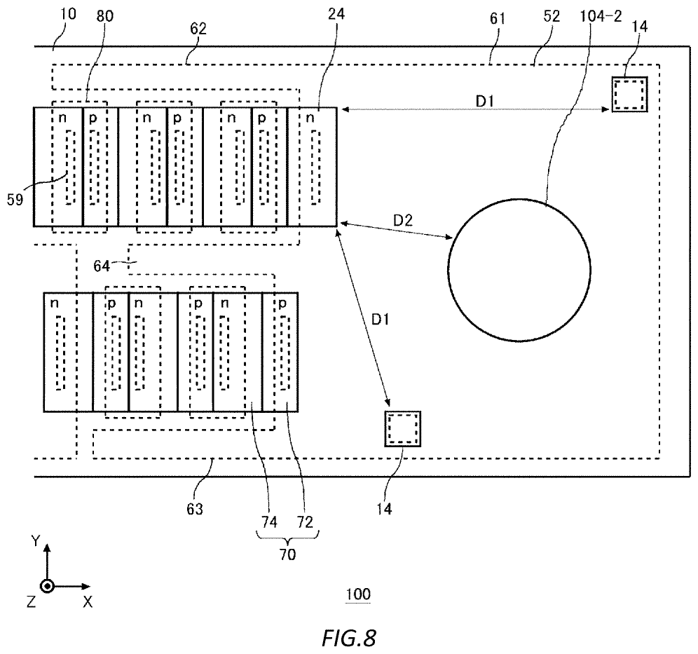

FIG. 8 illustrates another exemplary arrangement of the through-wire 14. In the present example, two through-wires 14 are provided to sandwich the contact portion 104-2. Any through-wire 14 may have the distance D1 larger than the distance D2 described above from the p-n junction diode 20. One through-wire 14 may be arranged close to the p-n junction diode 70 compared to the contact portion 104-2.

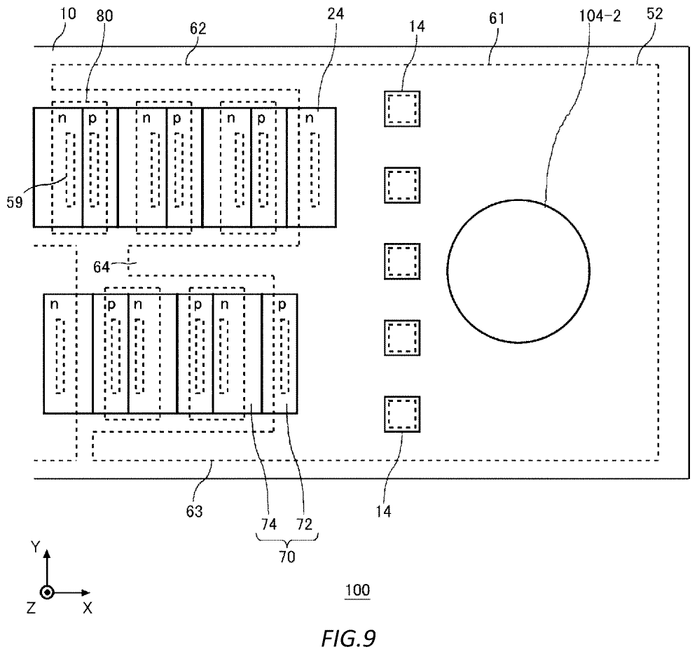

FIG. 9 illustrates another exemplary arrangement of the through-wire 14. In the present example, three or more through-wires 14 are arranged along the Y axis direction. In the example shown in FIG. 9, the through-wires 14 is provided in a region between the p-n junction diode 20 and the contact portion 104-2 in the X axis direction. Some through-wires 14 may be arranged or may not be arranged in the middle region 110 shown in FIG. 7. In another example, similar to the example shown in FIG. 6, three or more through-wires 14 may be arranged outside the contact portion 104-2 in the X axis direction.

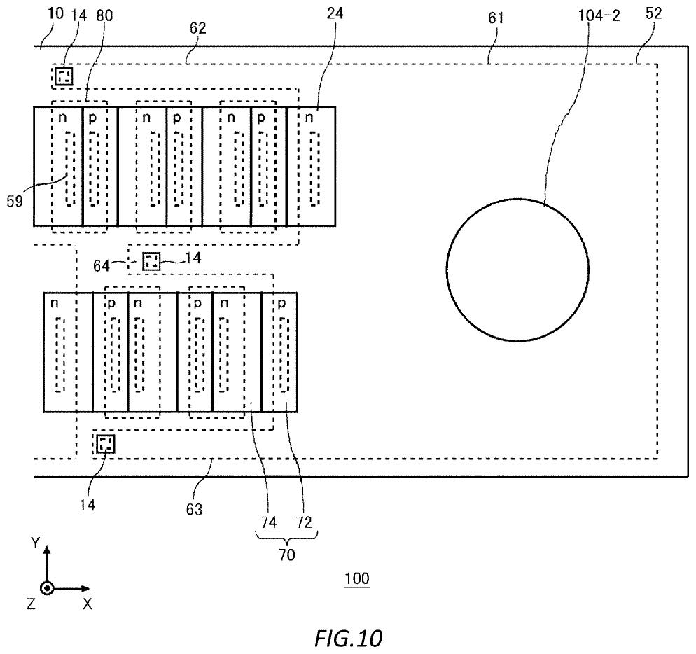

FIG. 10 illustrates another exemplary arrangement of the through-wire 14. In the present example, at least one through-wire 14 is provided in the second portion 62 of the cathode electrode 52. The plurality of through-wires 14 may be provided in the second portion 62. The plurality of through-wires 14 may be arranged side by side in the second portion 62 in the X axis direction. The current flowing from the p-n junction diode 20 to the through-wire 14 can be suppressed by providing the through-wire 14 in the second portion 62.

At least one through-wire 14 may be provided in the third portion 63 of the cathode electrode 52. The plurality of through-wires 14 may be provided in the third portion 63. The plurality of through-wires 14 may be arranged side by side in the third portion 63 in the X axis direction. The current flowing from the p-n junction diode 20 to the through-wire 14 can be suppressed by providing the through-wire 14 in the third portion 63.

At least one through-wire 14 may be provided in the fourth portion 64 of the cathode electrode 52. The plurality of through-wires 14 may be provided in the fourth portion 64. The plurality of through-wires 14 may be arranged side by side in the fourth portion 64 in the X axis direction. The current flowing from the p-n junction diode 20 to the through-wire 14 can be suppressed by providing the through-wire 14 in the fourth portion 64.

The through-wires 14 may be provided in either one or a plurality of the second portion 62, the third portion 63 and the fourth portion 64. The through-wires 14 may be provided in either one or a plurality of the second portion 62, the third portion 63 and the fourth portion 64. The through-wire 14 may be provided in all of the second portion 62, the third portion 63 and the fourth portion 64.

The exemplary arrangements of the through-wires 14 described in FIG. 4 to FIG. 10 can be properly combined. For example, the exemplary arrangement of the through-wires 14 in the second portion 62, the third portion 63 and the fourth portion 64 described in FIG. 10 may be combined with the exemplary arrangement of the through-wires 14 of the first portion 61 described in either one of FIG. 4 to FIG. 9.

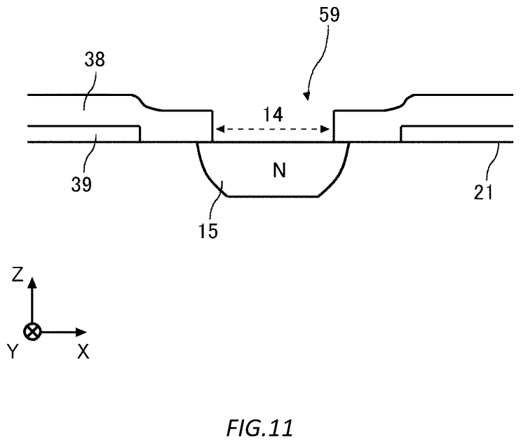

FIG. 11 illustrates an example of an A-A cross section in FIG. 5. The A-A cross section is an XZ plane passing through the through-wire 14. In FIG. 11, a cross section near the upper surface 21 of the semiconductor substrate 10 is shown.

In the present example, an initial oxide film 39 is formed on the upper surface 21 of the semiconductor substrate 10. The initial oxide film 39 in the region where the through-wire 14 is to be formed is partially etched and removed. Also, an interlayer dielectric film 38 such as a BPSG, above the upper surface 21 of the semiconductor substrate 10 is formed. Contact holes are formed by partially etching the interlayer dielectric film 38 of the region where the through-wire 14 is to be formed. The interlayer dielectric film 38 may remain inside the initial oxide film 39. A high concentration region 15 is formed by implanting dopant ions via the contact holes formed on the interlayer dielectric film 38. The through-wires 14 are formed by filling metal into the contact holes after forming the high concentration region 15.

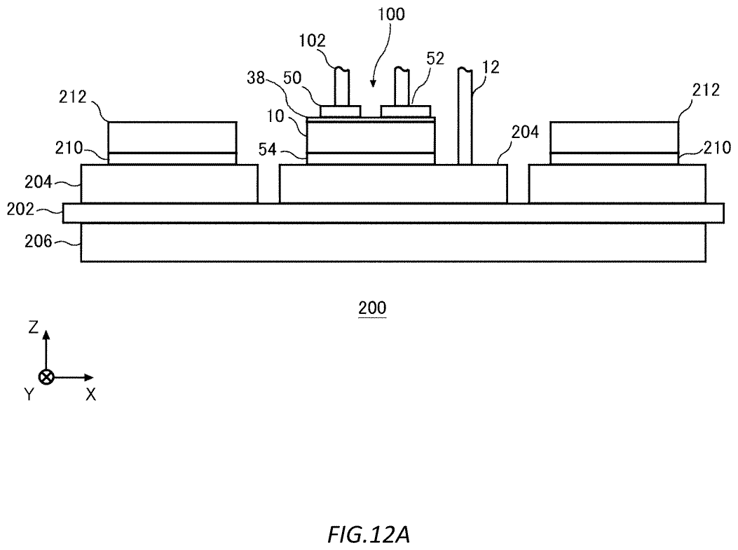

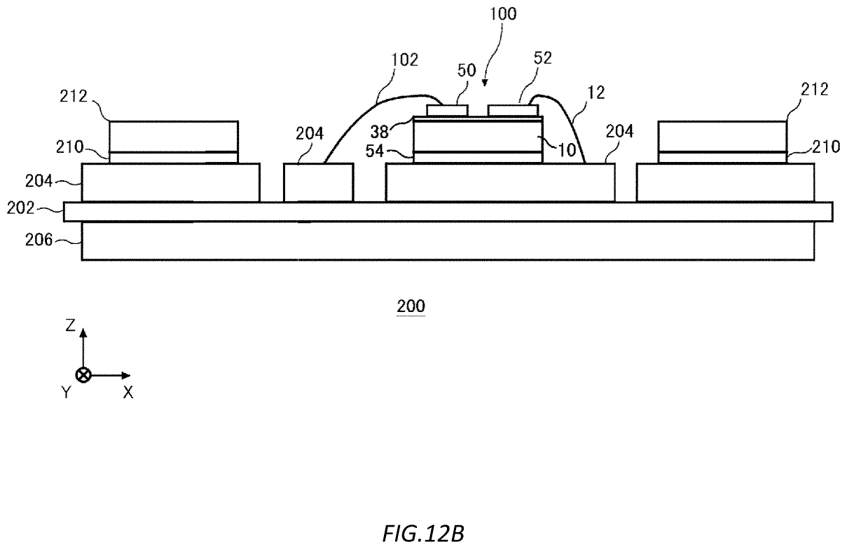

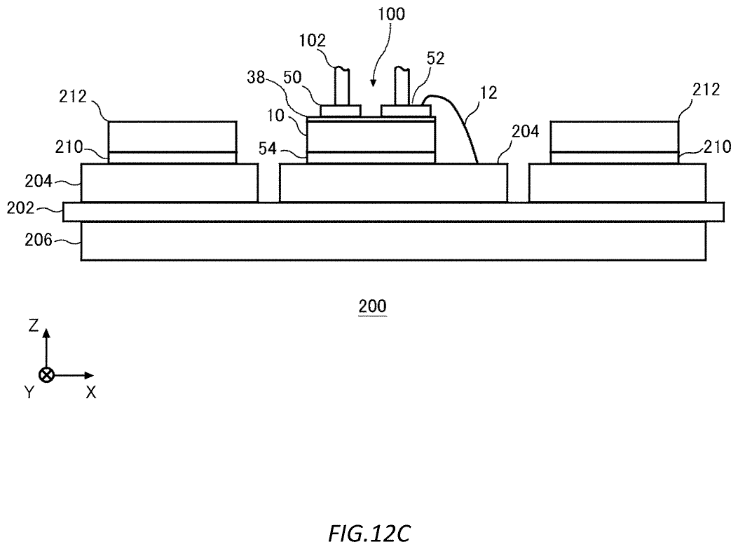

FIG. 12A to FIG. 12C illustrate another exemplary structure of the semiconductor module 200. In the present example, the structure of the conductive portion 12 is different from the example described in FIG. 1 to FIG. 11. The other portions are similar to the example described in FIG. 1 to FIG. 11.

In the present example, the conductive portion 12 is provided outside the semiconductor substrate 10 and electrically connects the cathode electrode 52 and the lower surface 23 of the semiconductor substrate. The conductive portion 12 may connect the wiring layer 204 for mounting the temperature detecting element 100 and the cathode electrode 52. In the present example, the conductive portion 12 is a rod-shaped pin, a board-shaped lead frame or a linear wire or the like. The conductive portion 12 may connect the wiring layer 204 and the cathode electrode 52 via another circuit board. With the present example, the discharge between the temperature detecting element 100 and the wiring layer 204 can also be suppressed.

FIG. 12A illustrates an example provided with a pin-shaped conductive portion 12. In the present example, the cathode electrode 52 is connected to the wiring layer 204 via the connection wiring line 102, the circuit board (not illustrated) and the conductive portion 12. In the present example, a cathode potential is applied to the cathode electrode 52 via the connection wiring line 102.

FIG. 12B illustrates an example provided with a wire-shaped conductive portion 12. In the present example, the cathode electrode 52 is connected to the wiring layer 204 via the conductive portion 12. The anode electrode 50 may also be connected to the wiring layer 204 by the wire-shaped connection wiring line 102.

FIG. 12C illustrates an example where a wire-shaped conductive portion 12 is provided. In the present example, the cathode electrode 52 is connected to the wiring layer 204 via the conductive portion 12. In the present example, a cathode potential is applied to the cathode electrode 52 via the connection wiring line 102.

The position where the conductive portion 12 is connected to the cathode electrode 52 in the example shown in FIG. 12C, may be similar to the position of any through-wire 14 described in FIG. 4 to FIG. 11. In the present example, a plurality of the conductive portions 12 may also be provided. In the examples described in FIG. 2 or the like, since the conductive portion 12 is provided inside the semiconductor substrate 10, the region that connects the conductive portions 12, such as wires, may not be provided in the wiring layer 204. Therefore, in the examples described in FIG. 2 or the like, in the semiconductor module 200, the area where the circuit of the semiconductor chip 212 or the like can be formed can be enlarged.

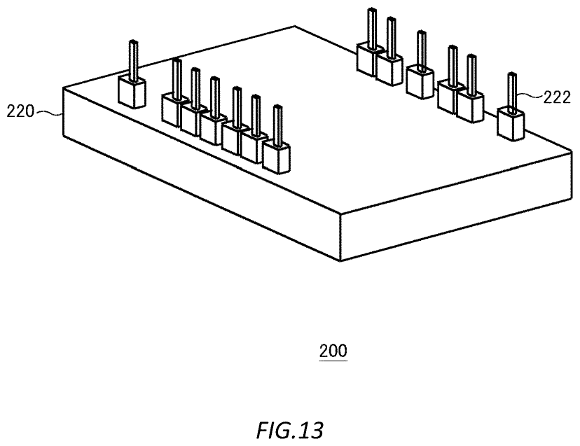

FIG. 13 illustrates a perspective view showing an example of the appearance of the semiconductor module 200. In the present example, the semiconductor module 200 has an enclosure 220 that houses each configuration described in FIG. 1 to FIG. 12C. The enclosure 220 is formed of an insulating material such as plastic or ceramic, or the like. In the enclosure 220, a plurality of connecting pins 222 are provided to connect the outside and the inside of the enclosure 220.

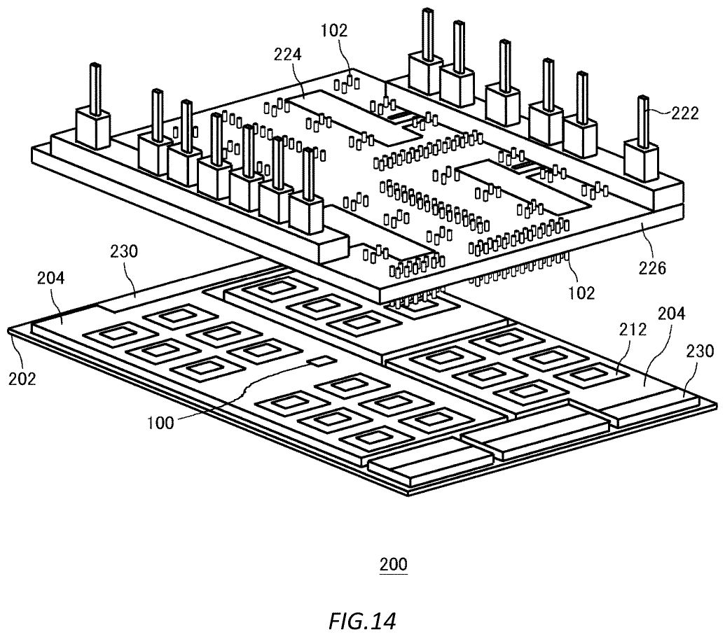

FIG. 14 illustrates a perspective view showing an example of a circuit housed in the enclosure 220. In the present example, the semiconductor module 200 has an insulating substrate 202 and a wiring line substrate 226. The configuration mounted on the insulating substrate 202 is similar to the example described in FIG. 1 to FIG. 12C. As shown in FIG. 14, a plurality of semiconductor chips 212 are provided in the wiring layer 204 of the insulating substrate 202. A pad 230 may be provided in the wiring layer 204. The temperature detecting element 100 is mounted on any wiring layer 204.

The temperature detecting element 100 may be arranged near the center of the insulating substrate 202, or may be arranged at another position. For example, the temperature detecting element 100 may be arranged in the central region of the nine regions formed when the long side and short side of the insulating substrate 202 are respectively divided into three equal parts. The temperature detecting element 100 may be arranged to be sandwiched between two semiconductor chips 212.

The wiring line substrate 226 is arranged to face a surface where the wiring layer 204 is provided on the insulating substrate 202. The wiring line substrate 226 has the connecting pins 222 described above provided thereon. Wirings, which connect the semiconductor chips 212 and each electrode of the temperature detecting element 100 to the connecting pins 222, are provided on the wiring line substrate 226.

In the present example, a plurality of connection wiring lines 102 are provided on the wiring line substrate 226. Each connection wiring line 102 may be a pin provided to penetrate the wiring line substrate 226. Multi-layer wirings connected to the connection wiring lines 102 may be formed inside the wiring line substrate 226. Wirings 224, such as copper patterns, may be provided on the surface of the wiring line substrate 226. The semiconductor chips 212 and the temperature detecting element 100 are connected to the connecting pins 222 by these wirings. The conductive portion 12 shown in FIG. 12A may connect the electrodes of the temperature detecting element 100 and the wiring layer 204 via the connection wiring lines 102 and the wiring line substrate 226.

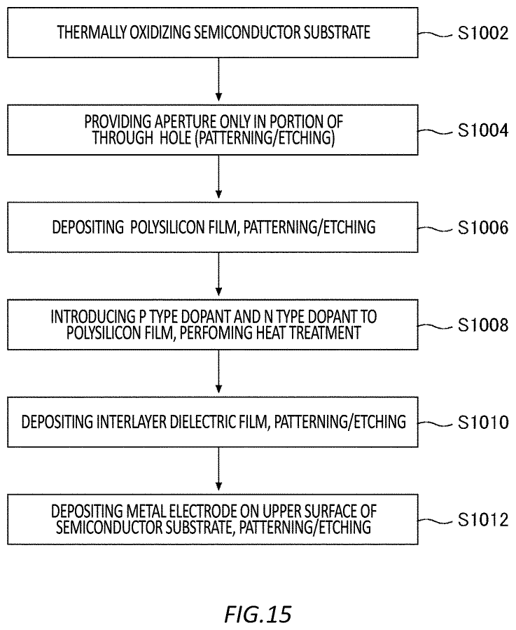

FIG. 15 illustrates a flow showing an example of a manufacturing method of the temperature detecting element 100. Thermally oxidizing the semiconductor substrate 10, and forming a semiconductor oxide film (initial oxide film 39) (S1002). Next, patterning a resist on the semiconductor oxide film, and etching only a portion where an aperture (a contact hole 59) is to be formed (S1004).

Subsequently, depositing a polycrystalline semiconductor film (polysilicon film) on the semiconductor oxide film selectively formed on the upper surface 21 of the semiconductor substrate 10 (the upper surface of the semiconductor oxide film in the present example). Next, performing patterning/etching such that the polysilicon film remains in a certain region (S1006).

Next, selectively form an N type cathode region and a P type anode region on the polycrystalline semiconductor film. In the present example, selectively introducing a P type dopant and an N type dopant to the polysilicon film described above, performing heat treatment to form a p-n junction diode 20 and a p-n junction diode 70 (1008). The P type dopant is, for example, boron. The N type dopant is, for example, arsenic. For example, boron is ion-implanted into the entire polysilicon film. Subsequently, patterning the resist on the polysilicon film, implanting arsenic into the aperture of the resist, making only the implantation region exposed at the aperture to be N type to form an N type contact layer (a high concentration region 15). The aperture of the resist corresponds to the cathode region and the N type contact layer in contact with the through hole. Performing heat treatment after stripping the resist (S1008).

Then, depositing the interlayer dielectric film 38 on the upper surface 21 side of the semiconductor substrate 10, and forming an aperture (a contact hole 59) on the interlayer dielectric film 38 by patterning and etching the resist (S1010). Next, depositing a metal electrode on the upper surface 21 side of the semiconductor substrate 10, and performing patterning/etching (S1012). In this manner, the through-wire 14 (the cathode electrode 52) and the high concentration region 15 are connected, and the conductive portion 12 is formed while forming the anode electrode 50 and the cathode electrode 52. Subsequently, an inactive protective film 37 (a polyimide film or the like) may be provided. Furthermore, the lower-surface electrode 54 is formed to contact the lower surface 23 of the semiconductor substrate 10.

Then, the temperature detecting element 100 is connected to the wiring layer 204 by solder or the like. Also, the wiring layer 204 and the pad portion 36 are electrically connected at the same potential as shown in the examples of FIG. 12A to FIG. 12C or the like. In this manner, the conductive portion 12 and the wiring layer 204 are electrically connected, the cathode electrode 52 and the wiring layer 204 are at the same potential, the discharge between the temperature detecting element 100 and the wiring layer 204 can be suppressed.

In the present specification, the following items are also disclosed.

### (Item 1)

A temperature detecting element formed on a semiconductor substrate with an upper surface and a lower surface, comprising:
an anode electrode and a cathode electrode provided above the upper surface of the semiconductor substrate;
a main cathode region of a first conductivity type connected to the cathode electrode;
a main anode region of a second conductivity type, which is provided in contact with the main cathode region and connected to the anode electrode; and
a conductive portion that connects one of the anode electrode or the cathode electrode to the lower surface of the semiconductor substrate at an identical potential.

### (Item 2)

The temperature detecting element according to item 1, comprising
a semiconductor oxide film on the upper surface of the semiconductor substrate,
wherein the main cathode region and the main anode region are formed on the upper surface of the semiconductor oxide film.

### (Item 3)

The temperature detecting element according to item 1 or 2, wherein
the main cathode region and the main anode region are formed on a polycrystalline semiconductor film.

### (Item 4)

The temperature detecting element according to item 2, wherein
the conductive portion is electrically connected to the cathode electrode and the lower surface of the semiconductor substrate.

### (Item 5)

The temperature detecting element according to item 4, wherein
the conductive portion has a conductive region of a first conductivity type provided inside the semiconductor substrate.

### (Item 6)

The temperature detecting element according to item 5, further comprising
an interlayer dielectric film provided between the upper surface of the semiconductor substrate and the cathode electrode,
wherein the conductive portion is provided to penetrate the interlayer dielectric film and the semiconductor oxide film, and has a through-wire connecting the cathode electrode and the conductive region.

### (Item 7)

The temperature detecting element according to item 6, wherein
the conductive region includes
a high concentration region connected to the through-wire; and
a low concentration region provided between the high concentration region and the lower surface of the semiconductor substrate, with a concentration lower than the high concentration region.

### (Item 8)

The temperature detecting element according to item 7, wherein
the low concentration region is provided below the main anode region and the main cathode region.

### (Item 9)

The temperature detecting element according to item 7 or 8, wherein
the conductive region is provided between the low concentration region and the lower surface of the semiconductor substrate, and further includes a lower surface region with a concentration higher than the low concentration region.

### (Item 10)

The temperature detecting element according to item 7 or 8, wherein
a resistivity of the low concentration region is 100 Ωcm or less.

### (Item 11)

The temperature detecting element according to item 7 or 8, wherein
a doping concentration of the low concentration region is 1×10¹³/cm³ or more.

### (Item 12)

The temperature detecting element according to item 1 or 2, wherein
a thickness between the upper surface of the semiconductor substrate and the lower surface is 10 μm or more and 300 μm or less.

### (Item 13)

The temperature detecting element according to any one of items 6 to 8, further comprising
a connection wiring line connected to the cathode electrode,
wherein an area of the through-wire is smaller than an area of a contact portion where the cathode electrode and the connection wiring line are brought into contact.

### (Item 14)

The temperature detecting element according to any one of items 6 to 8, further comprising
a connection wiring line connected to the cathode electrode,
wherein the through-wire is further away from the main anode region and the main cathode region than a contact portion where the cathode electrode and the connection wiring line are brought into contact.

### (Item 15)

The temperature detecting element according to any one of items 6 to 8, further comprising
a connection wiring line connected to the cathode electrode,
wherein the through-wire is further closer to the main anode region and the main cathode region than a contact portion where the cathode electrode and the connection wiring line are brought into contact.

### (Item 16)

The temperature detecting element according to any one of items 6 to 8, further comprising
a connection wiring line connected to the cathode electrode,
wherein at least one of the through-wire is provided outside a middle region between a contact portion where the cathode electrode and the connection wiring line are brought into contact and a set of the main anode region and the main cathode region.

### (Item 17)

The temperature detecting element according to any one of items 6 to 8, further comprising
a connection wiring line connected to the cathode electrode,
wherein the through-wire is provided in a region not overlapping a contact portion where the cathode electrode and the connection wiring line are brought into contact.

### (Item 18)

The temperature detecting element according to any one of items 6 to 8, wherein:
a plurality of through-wires are provided, each being the through-wire;

### (Item 19)

The temperature detecting element according to item 18, wherein:
the temperature detecting element further comprises a connection wiring line connected to the cathode electrode; and
two of the through-wires are provided to sandwich a contact portion where the cathode electrode and the connection wiring line are brought into contact.

### (Item 20)

The temperature detecting element according to any one of items 6 to 8, wherein:
the main anode region and the main cathode region are arranged side by side in a first direction; and
the cathode electrode has:
a first portion where the main anode region and the main cathode region are arranged side by side in the first direction; and
a second portion provided to extend from the first portion to a position where the main anode region and the main cathode region are arranged side by side in a second direction perpendicular to the first direction,
wherein the through-wire is provided in the second portion.

### (Item 21)

The temperature detecting element according to item 1 or 2, further comprising
a sub cathode region of a first conductivity type and a sub anode region of a second conductivity type, which are provided to be arranged in reverse parallel to the main anode region and the main cathode region.

### (Item 22)

The temperature detecting element according to item 21, wherein
each of the main anode regions and the main cathode regions are repeatedly arranged alternately one or more times;
each of the sub anode regions and the sub cathode regions are repeatedly arranged alternately for one or more times;
a number of times for which the sub anode regions and the sub cathode regions are repeatedly arranged is smaller than a number of times for which the main anode regions and the main cathode regions are repeatedly arranged.

### (Item 23)

The temperature detecting element according to item 1, wherein
the conductive portion is provided outside the semiconductor substrate, and electrically connects the cathode electrode and the lower surface of the semiconductor substrate.

### (Item 24)

A semiconductor module, comprising:
the temperature detecting element according to item 1; and
a circuit board for mounting the temperature detection element, wherein:
the lower surface of the semiconductor substrate and the circuit board are arranged to face each other; and
either the anode electrode or the cathode electrode is electrically connected to the circuit board via the conductive portion.

### (Item 25)

A manufacturing method of a temperature detecting element, comprising:
thermally oxidizing a semiconductor substrate to form a semiconductor oxide film;
forming an aperture in a portion of the semiconductor oxide film;
selectively forming a polycrystalline semiconductor film on an upper surface of the semiconductor substrate;
selectively forming a cathode region of a first conductivity type and an anode region of a second conductivity type on the polycrystalline semiconductor film, and simultaneously forming a high concentration region of a conductivity type identical to the semiconductor substrate on the upper surface of the semiconductor substrate exposed from the aperture of the semiconductor oxide film;
forming an interlayer dielectric film on an upper surface side of the semiconductor substrate;
selectively forming a metal electrode, forming an anode electrode connected to the anode region and a cathode electrode connected to the cathode region, and forming a conductive portion by connecting the cathode electrode and the high concentration region on the upper surface side of the semiconductor substrate; and
connecting the semiconductor substrate to a wiring layer, wherein the conductive portion is electrically connected to the wiring layer.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

What is claimed is:

1. A temperature detecting element formed on a semiconductor substrate with an upper surface and a lower surface, comprising:
an anode electrode and a cathode electrode provided above the upper surface of the semiconductor substrate;
a main cathode region of a first conductivity type connected to the cathode electrode;
a main anode region of a second conductivity type, which is provided in contact with the main cathode region and connected to the anode electrode; and
a conductive portion that connects one of the anode electrode or the cathode electrode to the lower surface of the semiconductor substrate at an identical potential.

2. The temperature detecting element according to claim 1, comprising
a semiconductor oxide film on the upper surface of the semiconductor substrate,
wherein the main cathode region and the main anode region are formed on the upper surface of the semiconductor oxide film.

3. The temperature detecting element according to claim 1, wherein
the main cathode region and the main anode region are formed on a polycrystalline semiconductor film.

4. The temperature detecting element according to claim 2, wherein
the conductive portion is electrically connected to the cathode electrode and the lower surface of the semiconductor substrate.

5. The temperature detecting element according to claim 4, wherein
the conductive portion has a conductive region of a first conductivity type provided inside the semiconductor substrate.

6. The temperature detecting element according to claim 5, further comprising
an interlayer dielectric film provided between the upper surface of the semiconductor substrate and the cathode electrode,
wherein the conductive portion is provided to penetrate the interlayer dielectric film and the semiconductor oxide film, and has a through-wire connecting the cathode electrode and the conductive region.

7. The temperature detecting element according to claim 6, wherein
the conductive region includes
a high concentration region connected to the through-wire; and
a low concentration region provided between the high concentration region and the lower surface of the semiconductor substrate, with a concentration lower than that of the high concentration region.

8. The temperature detecting element according to claim 7, wherein
the low concentration region is also provided below the main anode region and the main cathode region.

9. The temperature detecting element according to claim 7, wherein
the conductive region is provided between the low concentration region and the lower surface of the semiconductor substrate, and further includes a lower surface region with a concentration higher than the low concentration region.

10. The temperature detecting element according to claim 6, further comprising
a connection wiring line connected to the cathode electrode,
wherein an area of the through-wire is smaller than an area of a contact portion where the cathode electrode and the connection wiring line are brought into contact.

11. The temperature detecting element according to claim 6, further comprising
a connection wiring line connected to the cathode electrode,
wherein the through-wire is further away from the main anode region and the main cathode region than a contact portion where the cathode electrode and the connection wiring line are brought into contact.

12. The temperature detecting element according to claim 6, further comprising
a connection wiring line connected to the cathode electrode,
wherein the through-wire is further close to the main anode region and the main cathode region than a contact portion where the cathode electrode and the connection wiring line are brought into contact.

13. The temperature detecting element according to claim 6, further comprising
a connection wiring line connected to the cathode electrode,
wherein at least one of the through-wire is provided outside a middle region between a contact portion where the cathode electrode and the connection wiring line are brought into contact and a set of the main anode region and the main cathode region.

14. The temperature detecting element according to claim 6, further comprising
a connection wiring line connected to the cathode electrode,
wherein the through-wire is provided in a region not overlapping a contact portion where the cathode electrode and the connection wiring line are brought into contact.

15. The temperature detecting element according to claim 6, wherein:
a plurality of through-wires are provided, each being the through-wire;
the temperature detecting element further comprises a connection wiring line connected to the cathode electrode; and
two of the through-wires are provided to sandwich a contact portion where the cathode electrode and the connection wiring line are brought into contact.

16. The temperature detecting element according to claim 6, wherein:
the main anode region and the main cathode region are arranged side by side in a first direction; and
the cathode electrode has:
a first portion where the main anode region and the main cathode region are arranged side by side in the first direction; and
a second portion provided to extend from the first portion to a position where the main anode region and the main cathode region are arranged side by side in a second direction perpendicular to the first direction,
wherein the through-wire is provided in the second portion.

17. The temperature detecting element according to claim 1, further comprising
a sub cathode region of a first conductivity type and a sub anode region of a second conductivity type, which are provided to be arranged in reverse parallel to the main anode region and the main cathode region.

18. The temperature detecting element according to claim 1, wherein
the conductive portion is provided outside the semiconductor substrate, and electrically connects the cathode electrode and the lower surface of the semiconductor substrate.

19. A semiconductor module, comprising:
the temperature detecting element according to claim 1; and
a circuit board for mounting the temperature detection element, wherein:
the lower surface of the semiconductor substrate and the circuit board are arranged to face each other; and
either the anode electrode or the cathode electrode is electrically connected to the circuit board via the conductive portion.

20. A manufacturing method of a temperature detecting element, comprising:
thermally oxidizing a semiconductor substrate to form a semiconductor oxide film;
forming an aperture in a portion of the semiconductor oxide film;
selectively forming a polycrystalline semiconductor film on an upper surface of the semiconductor substrate;
selectively forming a cathode region of a first conductivity type and an anode region of a second conductivity type on the polycrystalline semiconductor film, and simultaneously forming a high concentration region of a conductivity type identical to the semiconductor substrate on the upper surface of the semiconductor substrate exposed from the aperture of the semiconductor oxide film;
forming an interlayer dielectric film on an upper surface side of the semiconductor substrate;
selectively forming a metal electrode, forming an anode electrode connected to the anode region and a cathode electrode connected to the cathode region, and forming a conductive portion by connecting the cathode electrode and the high concentration region on the upper surface side of the semiconductor substrate; and
connecting the semiconductor substrate to a wiring layer, wherein the conductive portion is electrically connected to the wiring layer.
